(19) United States
(12) Patent Application Publication
(10) Pub. No.: US 2013/0270661 A1
(43) Pub. Date: Oct. 17, 2013

(54) Magnetoresistive random access memory cell design

(71) Applicants: Ge Yi, San Ramon, CA (US); Shaoping Li, San Ramon, CA (US); Yunjun Tang, Pleasanton, CA (US); Zongrong Liu, Pleasanton, CA (US)

(72) Inventors: Ge Yi, San Ramon, CA (US); Shaoping Li, San Ramon, CA (US); Yunjun Tang, Pleasanton, CA (US); Zongrong Liu, Pleasanton, CA (US)

(21) Appl. No.: 13/448,133

(22) Filed: Apr. 16, 2012

(51) Int. Cl. H01L 29/82

(52) U.S. Cl. 257/421; 257/E29.323

(57) ABSTRACT

A new magnetic memory cell comprises a perpendicular-anisotropy tunneling magnetic junction (TMJ) and a fixed in-plane spin-polarizing layer, which is separated from the perpendicular-anisotropy data storage layer of tunneling magnetic junction by a non-magnetic layer. The non-magnetic layer can be made of metallic or dielectric materials.

### FIELD OF INVENTION

The invention is related to memory cell design for magnetoresistive random access memory (MRAM), more specifically design of a memory cell compromising perpendicular-anisotropy TMR sensing stack structure with perpendicular storage layer, whose magnetic orientation can be switched by spin polarization current injected from a fixed in-plane magnetic-anisotropy layer separated away by non-magnetic layer from storage layer.

### BACKGROUND ART

Data storage memory is one of the backbones of the modern information technology. Semiconductor memory in the form of DRAM, SRAM and flash memory has dominated the digital world for the last forty years. Comparing to DRAM based on transistor and capacitor above the gate of the transistor, SRAM using the state of a flip-flop with large form factor is more expensive to produce but generally faster and less power consumption. Nevertheless, both DRAM and SRAM are volatile memory, which means they lost the information stored once the power is removed. Flash memory on the other hand is non-volatile memory and cheap to manufacture. However, flash memory has limited endurances of writing cycle and slow write through the read is relatively faster.

MRAM is a relatively a new type of memory technologies. It has the speed of the SRAM, density of the DRAM and it is non-volatile as well. If it is used to replace the DRAM in computer, it will not only give “instant on” but “always-on” status for operation system and restore the system to the point when the system is power off last time. It could provide a single storage solution to replace separate cache (SRAM), memory (DRAM) and permanent storage (HDD or flash-based SSD) on portable device at least. Considering the growth of “cloud computing”, MRAM has a great potential and can be the key dominated technology in digital world.

MRAM storage the informative bit “1” or “0” into the two magnetic states in the so-called magnetic storage layer. The different states in the storage layer gives two distinctive voltage outputs from the whole memory cell, normally a patterned TMR or GMR stack structures. The TMR or GMR stack structures provide a read out mechanism sharing the same well-understood physics as current magnetic reader used in conventional hard disk drive.

There are two kinds of the existing MRAM technologies based on the write process: one kind, which can be labeled as the conventional magnetic field switched (toggle) MRAM, uses the magnetic field induced by the current in the remote write line to change the magnetization orientation in the data stored magnetic layer from one direction (for example “1”) to another direction (for example “0”). This kind of MRAM has more complicated cell structure and needs relative high write current (in the order of mA). It also has poor scalability beyond 65 nm because the write current in the write line needs to continue increase to ensure reliable switching the magnetization of a dimension shrinking magnetic stored layer because of the smaller the physical dimension of the storage layer, the higher the coercivity it normally has for the same materials. Nevertheless, the only commercially available MRAM so far is still based on this conventional writing scheme. The other class of the MRAM is called spin-transfer torque (STT) switching MRAM. It is believed that the STT-RAM has much better scalability due to its simple memory cell structure. While the data read out mechanism is still based on TMR effect, the data write is governed by physics of spin-transfer effect [1, 2]. Despite of intensive efforts and investment, even with the early demonstrated by Sony in late 2005[3], no commercial products are available on the market so far. One of the biggest challenges of STT-RAM is its reliability, which depends largely on the value and statistical distribution of the critical current density needed to flip the magnetic storage layers within the every patterned TMR stack used in the MRAM memory structures. Currently, the value of the critical current density is still in the range of 10⁶ A/cm². To allow such a large current density through the dielectric barrier layer such as AlOx and MgO in the TMR stack, the thickness of the barrier has to be relatively thin, which not only limits the magnetoresist (MR) ratio value but also cause potential risk of the barrier breakdown. As such, a large portion of efforts in the STT-RAM is focused on lower the critical current density while still maintaining the thermal stability of the magnetic data storage layer. Another challenge is related partially to the engineering challenge due to the imperfection of memory cell structure patterning (patterned TMR element) such as edge magnetic moment damage and size variation, as well as uniformity of the barrier thickness during the deposition and magnetic uniformity in the data storage layer and spin polarized magnetic layer (also called reference layer). This non-uniformity leads to variation of the size, edge roughness, magnetic uniformity and barrier thickness for patterned TMR elements, which ultimately cause the statistic variation of critical current density needed for each patterned cell.

The success of the STT-RAM largely depends on the breakthrough on the material used in STT-RAM, which give a fair balance between the barrier thickness (related to broken down voltage and TMR ratio), critical current density and thermal stability of the magnetic storage layer.

In this invention, we propose a few new perpendicular-anisotropy MRAM memory cell structures with assistant storage layer switching mechanism based on spin polarized current from the adjacent fixed magnetic layer with in plane magnetization, which is separated by non-magnetic layer from the storage layer.

### SUMMARY OF THE INVENTION

The present invention of the proposed memory cells for the new type of the MRAM includes a perpendicular-anisotropy magnetic tunneling junction, whose freely moving layer (free layer) acts as storage layer. The perpendicular magnetization of the free layer can be switched by polarized spin current via spin torque effect [1,2] injected from fixed in-plane ferromagnetic layer separated by non-magnetic layer from the storage layer.

### BRIEF DESCRIPTION OF THE DRAWINGS

FIG. 1 illustrates one of the embodiments of magnetic memory cell with magnetic tunneling junction locating at the bottom portion of the cell and sin polarized layer on the top part of the cell.

FIG. 2 illustrates one of the embodiments of magnetic memory cell with magnetic tunneling junction locating on the top portion of the cell and sin polarized layer at the bottom part of the cell.

FIG. 3 Illustrates one of the embodiments of a full stack structures for memory cell shown in FIG. 1A

### DETAILED DESCRIPTION

The following description is provided in the context of particular designs, applications and the details, to enable any person skilled in the art to make and use the invention. However, for those skilled in the art, it is apparent that various modifications to the embodiments shown can be practiced with the generic principles defined here, and without departing the spirit and scope of this invention. Thus, the present invention is not intended to be limited to the embodiments shown, but is to be accorded the widest scope consistent with the principles, features and teachings disclosed here.

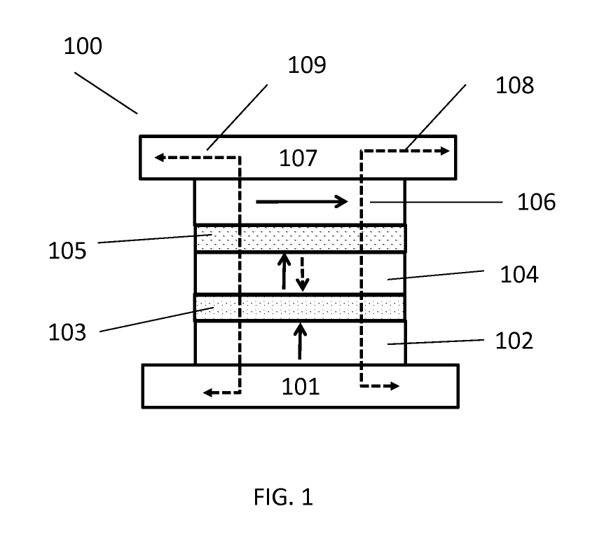

With reference of the FIG. 1 showing a magnetic memory cell 100, the proposed MRAM memory cell 100, counted from the material growth plane from the bottom, comprises a bottom electrode 101; perpendicular-anisotropy magnetic reference layer 102 with fixed magnetization orientation; tunneling barrier 103; perpendicular-anisotropy data storage layer 104; non-magnetic spacing layer 105; fixed in-plan magnetic-anisotropy layer 106 and top electrode 107. Above bottom electrode 101, there is a perpendicular-anisotropy magnetic reference layer 102, whose magnetization is fixed and represents here by an up-pointing arrow. Despite of the magnetization of layer 102 pointing up, the pre-set magnetization of the reference layer 102 can also have a down-pointing. Above the reference layer 102 is a dielectric tunneling barrier 103, which can be made of material such as MgO, CrOx, AlOx, TiOx or their combination with RA between 2-15 Ohm*um². Adjacent to dielectric tunneling barrier 103, there is perpendicular-anisotropy magnetic storage layer 104, which is made of the materials such as CoFeB, CoFeB/CoFe, Co/TbCoFe, Fe/CoFeB, CoFe/CoFeB, CoFeB/Co, CoFeB/TbCoFe, CoFeB/(CoFe/Pt)n, CoFeB/(CoFe/Pt)/CoFeB; CoFeB/TbCoFe/CoFeB, CoFeB/Co2FeAl, Co2FeAl, CoFeB/CoFeGe/CoFeB, CoFeB/TbFeCo, CoFeB/TbFeCo/CoFeB etc. The combination of the perpendicular-anisotropy magnetic reference layer 102, the tunneling barrier 103 and perpendicular-anisotropy magnetic storage layer 104 forms a magnetic tunneling junction, which can be used to sense the relative orientation relation between the magnetization of the magnetic reference layer 102 and data storage layer 104. When the relative orientation of magnetization of the layer 102 and layer 104 is the same, for example up-pointing, the output voltage will be low while sensing current 108 passing through. On the other hand, if magnetization of the layer 102 points up while that of the layer 104 points down (dot-line arrow in this case), the out-put voltage will be high. Above the data storage layer 104 is a non-magnetic space layer 105, which can be made of either metallic materials such as Cu, Ag, Au, Al, Ru etc. or dielectric materials such as MgO, AlOx, TiOx or CrOx etc, or the composite materials made of the mixture between dielectric materials and metallic material mentioned above. Using dielectric or composite space layer can increase spin polarization at the interface between the fixed in-plane spin polarized layer and space layer, which effectively reduces the critical current needed to switch the data storage layer. However, it does increase the overall parasitic resistance of the memory cell and reduce the MR ratio (deltR/R) of the stack. To balance the design requirements between high RA ratio and low critical current during writing, the RA of the space layer need to be low comparing with RA of the tunneling junction barrier. On top of the layer 105 is a fixed in-plane magnetic-anisotropy spin-polarized layer 106. The fixed magnetization orientation in the spin-polarized layer 106 provides a fixed bias field to the adjacent storage layer 104 due to flux emitted from the layer. When writing current 109 is passing through the layer 106, the current 109 will get spin polarized. As the current 109 through the data storage layer 104, based on theory [1,2,8], the magnetization of data storage layer 104 will be switched to opposite direction from its original direction at deterministic fashion under the influence of the spin torque as well the biased field from the fixed in-plane spin-polarized layer. An up-electrode 107 is over the spin-polarizing layer 106 to protect the layer 106 as well as conduce both sensing current 108 and writing current 109 into the memory cell 100. As to the perpendicular-anisotropy reference layer 102, it can be a magnetic single layer, or multilayer or even a synthetic antiferromagnetic layer [5] with perpendicular anisotropy. If layer 102 is a single layer, it can be made of magnetic single layer such as CoPt/CoFeB. The layer 102 can be made of magnetic multilayer (repeat n times) consisting of magnetic layer and non-magnetic layer, such as (Co/Pt)n, (CoFe/Pt)n, (CoFe/Pd)n, (CoNi/Pt)n, (Co/Pd)n, (CoNi/Pd)n, (Fe/Au)n, (FoCo/Au)n, (CoFeB/Pd)n, (CoFeB/Pt)n as well as the above multilayer adding CoFe or CoFeB etc. More complicated synthetic antiferromagnetic with perpendicular anisotropy can be made from non-magnetic layer, such as Ru, Rh, Cu sandwiched between two perpendicular-anisotropy magnetic single layers or magnetic multilayer, one of which is coupled to anitoferromagnetic layer such as IrMn. The magnetic layer can made of (CoPt)n/CoFe/Ru/CoFe(CoPt)n, CoPt/Ru/CoFeB, CoPt/Co/Ru/Co/CoFeB, (Co/Pt)n/Ru/CoFeB. As to the fixed spin-polarizing layer 106, it can be either in-plane magnetic-anisotropy single layer e.g. CoFe/CoCrPt, CoFe/CoFeB/CoPt or in-plane synthetic antiferromagnetic layer [5] such as CoFe/Ru/CoFe with one of ferromagnetic layer coupled to an antiferromagnetic layer such as IrMn.

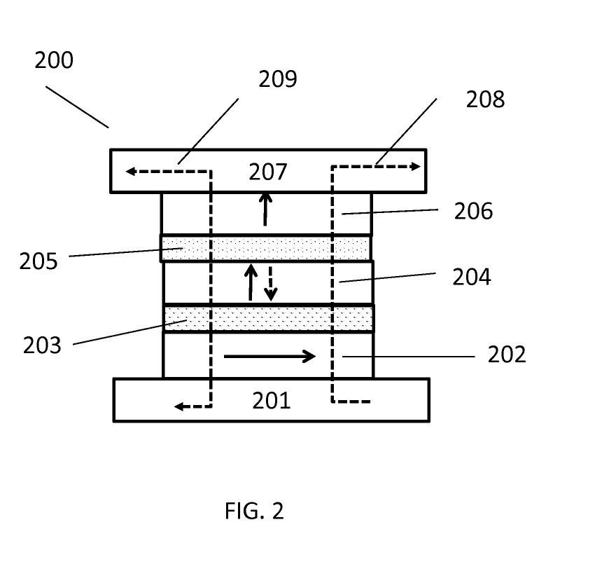

With reference of the FIG. 2 showing a magnetic memory cell 200, the proposed MRAM memory cell 200, counted from the material growth plane from the bottom, comprises a bottom electrode 201; an fixed in-plan magnetic-anisotropy layer 202; a non-magnetic spacing layer 203; a perpendicular-anisotropy data storage layer 204; a tunneling barrier 205; a perpendicular-anisotropy magnetic reference layer 206; and a top electrode 207. Below top electrode layer 207, there is a perpendicular-anisotropy magnetic reference layer 206, whose magnetization is fixed and represents here by an up-pointing arrow. Despite of the magnetization of layer 206 pointing up, the pre-set magnetization of the reference layer 206 can also have a down-pointing. Below the reference layer 206 is a dielectric tunneling barrier 205, which can be made of material such as MgO, CrOx, AlOx, TiOx or their combination. Beneath the dielectric tunneling barrier 205, there is perpendicular-anisotropy magnetic storage layer 204, which is made of the materials such as CoFeB, CoFeB/CoFe, Co/TbCoFe, Fe/CoFeB, CoFe/CoFeB, CoFeB/Co, CoFeB/TbCoFe, CoFeB/(CoFe/Pt)n, CoFeB/(CoFe/Pt)/CoFeB; CoFeB/TbCoFe/CoFeB, CoFeB/Co2FeAl, Co2FeAl, CoFeB/CoFeGe/CoFeB, CoFeB/TbFeCo, CoFeB/TbFeCo/CoFeB etc. The combination of the perpendicular-anisotropy magnetic reference layer 206, the tunneling barrier 205 and perpendicular-anisotropy magnetic storage layer 204 forms a magnetic tunneling junction, which can be used to sense the relative orientation relation between the magnetization of the magnetic reference layer 206 and data storage layer 204. When the relative orientation of magnetization of the layer 206 and layer 204 is the same, for example up-pointing, the output voltage will be low while sensing current 208 passing through. On the other hand, if magnetization of the layer 206 points up while that of the layer 204 points down (dot-line arrow in this case), the out-put voltage will be high. Below the data storage layer 204 is a non-magnetic spacing layer 203, which can be made of either metallic materials such as Cu, Ag, Au, Al, Ru etc. or dielectric materials such as MgO, AlOx, TiOx or CrOx etc, or the composite materials made of the mixture between dielectric materials and metallic material mentioned above. Using dielectric or composite space layer can increase spin polarization at the interface between the fixed in-plane spin polarized layer and space layer, which effectively reduces the critical current needed to switch the data storage layer. However, it does increase the overall parasitic resistance of the memory cell and reduce the MR ratio (deltR/R) of the stack. To balance the design requirements between high RA ratio and low critical current during writing, the RA of the space layer need to be low comparing with RA of the tunneling junction barrier. Below the layer 203 is a fixed in-plane magnetic-anisotropy spin-polarizing layer 202. The fixed magnetization orientation in the spin-polarized layer 202 provides a fixed bias field to the adjacent storage layer 204 due to flux emitted from the layer. When writing current 209 is passing through the layer 202, the current 209 will get spin polarized, As the current 209 through the data storage layer 204, based on theory [1,2,8], the magnetization of data storage layer 204 will be switched to opposite direction from its original direction at deterministic fashion under the influence of the spin torque as well the biased field from the fixed in-plane spin-polarized layer. A bottom-electrode 201 is below the spin-polarizing layer 202 and it conduces both sensing current 208 and writing current 209 into the memory cell 200. As to the perpendicular-anisotropy reference layer 206, it can be a magnetic single layer, or multilayer or even a synthetic antiferromagnetic layer [5] with perpendicular anisotropy. If layer 206 is a single layer, it can be made of magnetic single layer such as CoPt/CoFeB. The layer 206 can also be made of magnetic multilayer (repeat n times) consisting of magnetic layer and non-magnetic layer, such as (Co/Pt)n, (CoFe/Pt)n, (CoFe/Pd)n, (CoNi/Pt)n, (Co/Pd)n, (CoNi/Pd)n, (Fe/Au)n, (FoCo/Au)n, (CoFeB/Pd)n, (CoFeB/Pt)n as well as the above multilayer adding CoFe or CoFeB etc. More complicated synthetic antiferromagnetic with perpendicular anisotropy can be made from non-magnetic layer, such as Ru, Rh, Cu sandwiched between two perpendicular-anisotropy magnetic single layers or magnetic multilayer, one of which is coupled to anitoferromagnetic layer such as IrMn. The magnetic layer can made of (CoPt)n/CoFe/Ru/CoFe(CoPt)n, CoPt/Ru/CoFeB, CoPt/Co/Ru/Co/CoFeB, (Co/Pt)n/Ru/CoFeB. As to the fixed spin-polarizing layer 202, it can be either in-plane magnetic-anisotropy single layer e.g. CoFe/CoCrPt, CoFe/CoFeB/CoPt or in-plane synthetic antiferromagnetic layer [5] such as CoFe/Ru/CoFe with one of ferromagnetic layer coupled to an antiferromagnetic layer such as IrMn.

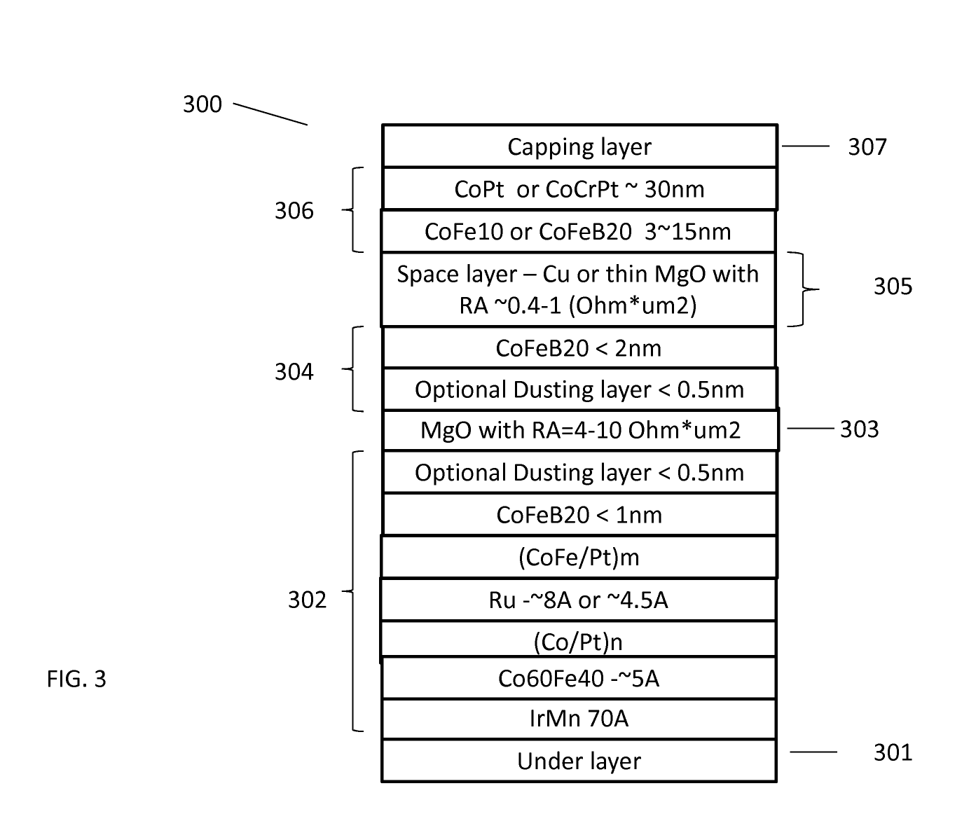

FIG. 3 shows an example of detailed materials stack structure 300 for MRAM cell of FIG. 1A. Although not detailed stack configuration is given for MRAM cell shown in FIG. 1B, FIG. 2A and FIG. 2B, based on the principles show here, similar stacks can be designed to match the requirements of the each individual. With reference of the stack 300, its consist under layer 301 (or layer structures) for control of the grain size and grain orientation in antiferromagnetic IrMn; perpendicular-anisotropy reference layer (structure) 302; tunneling barrier 301; perpendicular-anisotropy storage layer (structure) 304; non-magnetic space layer 305; fixed in-plane magnetic layer (structure) 306 for spin polarization and stack capping layer (or layer structure) 307. It is noted that the layer and layer structure are used inter-changeably in the above description. For magnetic functional layer particularly, even there are multiple layers existing in one functional layer, since they are strongly coupled magnetically, they act as single magnetic layer under extend field or spin current. For non-magnetic such as under-layer or capping layer, they may also involve multiple layers to fulfill the one particular function. For those reasons, we describe as one layer but we would like to point out clearly that one functional layer could have layer structures involving multiple layers. As to reference layer 302 in this case, it consist a synthetically antiferromagnetic layer structure, which has IrMn 70-90 A; coupling enhancement layer Co60Fe40 5 A; perpendicular multilayer (Co/Pt)n (n=3-8); Ru (˜8 A or 4.5 A) to introduce RKKY couple between two adjacent magnetic layers; multilayer (CoFe/Pr)m (m=3-5); spin enhancement and barrier texture control layer CoFeB20 with thickness less than 1 nm; and optional interface dusting layer for MR enhancement, whose thickness less than 5 A. The perpendicular free layer 304 consists optional interface dusting layer for enhancing MR value and CoFeB20 with less than 2 nm as a perpendicular magnetic layer. The tunneling barrier 303 is MgO with targeted RA between 4-10 Ohm*um2 pending on the choice of the materials for spacer layer 305. If metallic layer such as Cu is chosen as space layer, the targeted barrier RA could be lower as there is less parasitic resistance from the spin-polarized block above the TMJ. If dielectric layer such as MgO is used as space layer 305, the barrier RA needs to be high and the RA for MgO of the space layer needs to be lower (0.4-1 Ohm*um2) to reduce the parasitic resistance so that the design can gain benefits of high spin polarization for reduction of critical current needed to flip the storage layer while it will not reduce the overall MR too much so as to still give enough signal-to-noise ratio for sensing voltage output. The fixed in-plane spin-polarization layer 306 consists spin enhance layer CoFe10 or CoFeB20 with thickness from 5-15 nm and top hard magnetic layer CoPt or CoPtCr (thickness ˜30 nm) pending on which materials is used as space layer. For dielectric space layer MgO, CoFeB20 with thickness large than 3 nm will be used.

What is claimed is:

1. A magnetic memory device, comprising:
a perpendicular-anisotropy magnetic reference layer (or layer structures) whose magnetization is fixed;
a perpendicular-anisotropy magnetic storage layer (or layer structure) whose magnetization can be changed is changeable;
a dielectric layer as tunneling barrier sandwiched between said perpendicular-anisotropy magnetic reference layer and said perpendicular-anisotropy magnetic storage layer;
a fixed in-plane anisotropy magnetic layer (or layer structure) where any current passing through gets spin polarized;
a non-magnetic layer sandwiched between said perpendicular-anisotropy magnetic storage layer and said fixed in-plan anisotropy magnetic layer.

2. The magnetic memory device of claim 1, wherein said perpendicular-anisotropy reference layer can be made of magnetic single layer such as CoPt/CoFeB; TbCo/CoFeB, CoPt/Co, TbCoFe/Co, CoFeGe/CoFeB, TbCoFe/CoFeB, Co2FeAl/CoFeB, FePt-L10 or magnetic multilayer (repeat n times) consisting of magnetic layer and non-magnetic layer such as (Co/Pt)n, (CoNi/Pt)n, (Co/Pd)n, (CoNi/Pd)n, (Fe/Au)n, (FoCo/Au)n, (CoFeB/Pd)n, (CoFeB/Pt)n, (Fe/Pt)n, (CoFe/Pt)n, (CoFe/Pd)n etc.

3. The magnetic memory device of claim 1, wherein said perpendicular-anisotropy reference layer can be is made of special non-magnetic layer sandwiched between two perpendicular-anisotropy ferromagnetic layers, with one of which is coupled with antiferromagnetic layer such as IrMn.

4. The magnetic structure of claim 3, wherein said special non-magnetic layer can be Ru, Cu, Rh, Pd, Pt or similar, which can introduce introduces RKKY coupling between said two ferromagnetic layers in claim 3.

5. The magnetic structure of claim 3, wherein materials of the two perpendicular-anisotropy ferromagnetic layers can be are either the same or different and are made of materials such as Co, TbCo, CoCrPt, CoPt, FePt-L10, CoZrPt, FeCoCr, FeCoPt, AINiCo, FeCrPd, CoFeB, TbFeCo, CoFe, Co2FeAl, CoFeGe or their combinations etc.

6. The magnetic structure of claim 3, wherein materials of the two perpendicular-anisotropy ferromagnetic layers can be are either the same or different and are made of multilayer materials (repeat n time) such as (Co/Pt)n, (CoNi/Pt)n, (Co/Pd)n, (CoNi/Pd)n, (Fe/Au)n, (FoCo/Au)n, (CoFeB/Pd)n, (CoFeB/Pt)n, (Fe/Pt)n etc.

7. The magnetic memory device of claim 1, wherein said perpendicular-anisotropy magnetic storage layer can be is made of CoFeB, or CoFeB/TbCoFe, or Co/CoFeB, or CoFe/CoFeB, or CoFeB/Co, or CoFeB/CoFeTb/CoFeB, or Co/TbCo/Co, or Co/TbCoFe/Co, or Co2FeAl/CoFeB, or CoFeGe/CoFeB, or FePt/CoFeB, or CoFeB/FePt/CoFeB, or CoFeB/(CoFe/Pt)n, or CoFe/(CoFe/Pd)n, or CoFeB/(CoFe/Pt)n/CoFe, or CoFe/(CoFe/Pd)n/CoFe or their combinations etc.

8. The magnetic memory device of claim 1, wherein said dielectric layer can be is made of MgO, or AlOx, or CrOx, or TiOx etc.

9. The magnetic memory device of claim 1, wherein said fixed in-plane anisotropy magnetic layer can be is made of CoFe/CoCr, or CoFe/CoCrPt, or CoNiFe/CoCrPt, or FeCoNi/CoCrPt, or CoFeB/CoCr, or CoFeB/CoCrPt, or CoFeB/CoCrPd, or CoFe/CoCrPd, or CoFe/CoPt, or CoFeNi/CoPt, or CoNi/CoPt, or their combinations.

10. The magnetic memory device of claim 1, wherein said fixed in-plane anisotropy magnetic layer can be is made of special non-magnetic layer sandwiched between two in-plane magnetic-anisotropy ferromagnetic layers with, with one of which is coupled with antiferromagnetic layer such as IrMn.

11. The magnetic structure of claim 10, wherein said special non-magnetic layer can be Ru, Cu, Rh, Pt, Pd or similar, which can introduce introduces RKKY coupling between said two ferromagnetic layers in claim 10.

12. The magnetic structure of claim 10, wherein materials of the two perpendicular-anisotropy ferromagnetic layers can be are either the same or different and are made of materials such as CoFe, CoNiFe, Co, Fe, CoNi, CoFeB, FeCo, CoCrPt, CoCr, CoCrPt, CoPt, CoPd or their combinations.

13. The magnetic memory device of claim 1, wherein said fixed in-plane anisotropy magnetic layer can be is made of synthetic ferromagnetic layer adjacent to a an antiferromagnetic layer such as CoFe/Ru/CoFe/IrMn, IrMn/CoFe/Ru/CoFe or similar structure.

14. The magnetic memory device of claim 1, wherein said non-magnetic layer can be is made of metallic layer such as Cu, Al, Ru etc, whose thickness is smaller than spin diffusion length of electron at predetermined working temperature of said magnetic memory device in claim 1.

15. The magnetic memory device of claim 1, wherein said non-magnetic layer can be is made of dielectric or semiconductor layer such as AlOx, MgOx, CrOx, ZnOx, TiOx etc, whose thickness and resistance-area product (RA) is are smaller than those of those of said dielectric layer as tunneling barrier.
